(19) United States
(12) Patent Application Publication
(10) Pub. No.: US 2006/0084243 A1
(43) Pub. Date: Apr. 20, 2006

(54) Oxidation sidewall image transfer patterning method

(76) Inventors: Ying Zhang, Yorktown Heights, NY (US); Hongwen Yan, Somers, NY (US); Oingyun Yang, Poughkeepsie, NY (US)

Correspondence Address: INNOVATION INTERFACE, LLC, 303 TABER AVENUE, PROVIDENCE, RI, 02906, US

(21) Appl. No.: 10/969,466

(22) Filed: Oct. 20, 2004

(51) Int. Cl. H01L 21/20

(52) U.S. Cl. 438/478; 438/482; 438/585; 438/587

(57) ABSTRACT

A method is presented for patterning a MOSFET gate which includes the steps of: forming a layer of gate material over a gate dielectric, depositing an amorphous Si layer over the gate material, depositing a nitride cap-layer on top of the amorphous Si layer, patterning the nitride cap-layer and the amorphous Si layer which results in exposed sidewalls on the amorphous Si layer, growing oxide strips on the sidewalls, removing the patterned nitride cap-layer and the amorphous Si layer while leaving the oxide strips in place, and using the oxide strips as masks in the patterning of the gate material.

### FIELD OF THE INVENTION

The present invention relates to precisely patterned small feature sizes, which are needed, for instance, in microelectronics, or more specifically in the fabrication of field effect devices.

### BACKGROUND OF THE INVENTION

Today's integrated circuits include a vast number of devices. Smaller devices and shrinking ground rules are the key to enhance performance and to improve reliability. As FET (Field-Effect-Transistor) devices are being scaled down, the technology becomes more complex. One of the problems in reaching ever smaller device dimensions is related to patterning small features. At any given technology level typically the gate length of FET devices has the smallest dimension. Throughout the history of microelectronics efforts have been expended on the realization of short gate lengths.

For semiconductor devices, such as MOSFET (Metal Oxide Semiconductor Field-Effect-Transistor, a name with historical connotations, meaning in general an insulated gate FET) devices with sub 30 nm ground rules, gate patterning with photolithography becomes extremely challenging. Shrinking photoresist thickness, for instance only about 130-150 nm for 193 nm wavelength at 45 nm ground rules, is making the use of photoresist as mask very difficult. The thinness of the resist makes it challenging to etch the layers to be patterned. For the 157 nm wavelength generation of photoresists, expected to be employed in the generation of 30 nm gate lengths, this problem will be further exacerbated. Furthermore, due to the resist inherited molecular structure size, the resist development processes, and the limits of photolithographic technology, the line edge roughness (LER) of the resist has reached intolerable levels. For example, the LER is typically 3 to 5 nm at a 25 nm gate length, which is about than 12%-20% of the total line width. With gate length shrinking, LER alone may well be a limiting factor as it could even break sub-10 nm gate lines.

Alternatives to the photolithographic process in patterning have already been explored in the art. One such method is the spacer image transfer (SIT) method which has a relatively long history, commencing with the publication: C. Johnson et al., “Method of Making Submicron Dimensions in Structures Using Sidewall Image Transfer Techniques”, IBM Technical Disclosure Bulletin, vol. 26, No. 9, February 1984, pp. 4587-4589. The SIT method uses sidewall deposition and etching properties for creating thin lines. FIG. 1 shows a schematic cross sectional view of a representative state in the prior art SIT method. On an article 30, which is in need to be patterned, an island 20 is defined. This island is conformally covered by a layer, which subsequently is being directionally, namely vertically, etched. The end result of these etching steps are spacers 10 on the sidewalls of island 20. Once the island 20 is removed the spacers 10 can be used for masking.

Various SIT method implementations have been devised, for instance in: U.S. Pat. No. 5,024,971 to Baker, “Method for patterning submicron openings using an image reversal layer of material”, or in U.S. Pat. No. 6,566,759 to Conrad, “Self-aligned contact areas for sidewall image transfer formed conductors” both incorporated herein by reference, but none teaches the present invention.

The SIT method has its limitations, not the least the so called “footing problem”. This problem of the SIT arises because, due to the manner in which the spacers are formed, the bottom of the spacers is typically thicker than their top part, as schematically depicted in FIG. 1. Such a foot typically gives a rough edge to one side of the spacer, resulting in a non uniform width of the spacer. Such a one-sided LER of the spacer makes the LER of the final product, such as the gate, inevitably even worse.

### SUMMARY OF THE INVENTION

In view of the problems discussed above this invention discloses a method for patterning with an oxidation sidewall process; making use of the precision with which dimensions can be controlled in an oxidation, and of the various selective etching techniques available in the art.

A method is disclosed for patterning an article, comprising the steps of: forming a silicon comprising layer over the article, when the silicon comprising layer is having at least one sidewall; growing an oxide strip on the at least one sidewall; removing the silicon comprising layer while leaving in place the oxide strip; and using the oxide strip as mask in the patterning of the article.

A method is further disclosed for patterning gates for MOSFETs, comprising the steps of: forming a layer of a first material over a gate dielectric, when the first material is suitable for being the gate material of a MOSFET; depositing an amorphous Si layer of between about 2 nm and 70 nm thickness; depositing a nitride cap-layer on top of the amorphous Si layer; patterning the nitride cap-layer and the amorphous Si layer, when sidewalls are exposed on the amorphous Si layer; growing oxide strips on the sidewalls to a thickness of between about 1 nm and 50 nm; removing remainder of the nitride cap-layer and the amorphous Si layer while leaving in place the oxide strips; and using the oxide strips as mask in the patterning of the first material, whereby forming the gates.

A method if further disclosed for fabricating an electronic processor comprising MOSFET devices, comprising the step of: patterning gates for the MOSFET devices, further comprising the step of: forming a layer of a first material over a gate dielectric, when the first material is suitable for being the gate material of a MOSFET; depositing an amorphous Si layer of between about 10 nm and 70 nm thickness; depositing a nitride cap-layer on top of the amorphous Si layer; patterning the nitride cap-layer and the amorphous Si layer, when sidewalls are exposed on the amorphous Si layer; growing oxide strips on the sidewalls to a thickness of between about 1 nm and 50 nm; removing remainder of the nitride cap-layer and the amorphous Si layer while leaving in place the oxide strips; and using the oxide strips as mask in the patterning of the first material, whereby forming the gates.

### BRIEF DESCRIPTION OF THE DRAWINGS

These and other features of the present invention will become apparent from the accompanying detailed description and drawings, wherein:

FIG. 1 shows a schematic cross sectional view of a representative state in the prior art spacer image transfer method;

FIG. 2 shows a schematic cross sectional view of a representative state in the disclosed oxidation sidewall image transfer method;

FIGS. 3 to 10 show schematic cross sectional views of an exemplary embodiment in the process steps for MOSFET gate fabrication using oxidation sidewall image transfer patterning; and

FIG. 11 shows a symbolic representation of a processor having a chip containing MOSFET gates fabricated using the oxidation sidewall image transfer method.

### DETAILED DESCRIPTION OF THE INVENTION

FIG. 2 shows a schematic cross sectional view of a representative state in the disclosed oxidation sidewall image transfer process. The article 30 is in need to be patterned. The term patterning means that some feature on the article 30 has to be defined by a mask, and a complementary of the defined feature, or the defined feature, has to be removed, typically by some etching technique. In this manner the blanket article 30 acquires a pattern. The mask for such a patterning in this invention is the oxidized sidewall 100 of the silicon comprising layer 110. In a representative embodiment the silicon comprising layer is amorphous Si.

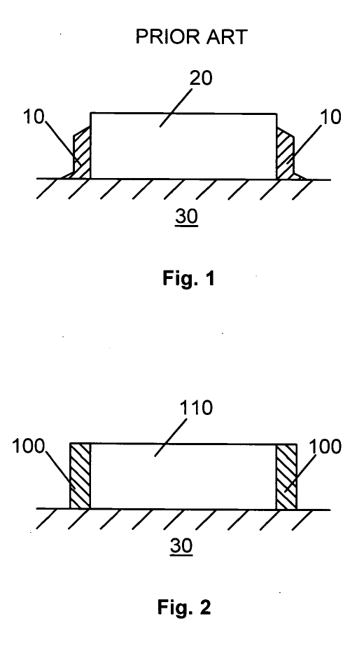

The method for using oxidized sidewall 100 for mask has several advantages. The oxidized sidewall does not have the limitations of lithographic technology, including such barriers as resist thickness, light wavelength size, and LER. The line width control of the oxidized sidewall technique is excellent due to the extremely uniform silicon oxidation process. Current silicon oxidation technologies can deliver oxide thicknesses as thin as 1 nm, across a 300 mm wafer, with a uniformity of less than 0.1 nm variation, or a 3 sigma of less than 3%. The oxidized sidewall avoids the so called “footing” issue of the SIT method in the prior art, which was shown in FIG. 1. The oxidized sidewall also avoids the so called “loading effect” of SIT. The “loading effect” is due to the fact that the thickness of a deposited sidewall/spacer layer depends upon the local topographic nature (such as local feature density and feature height variation) of the pattern, and can also vary across the wafer, e.g. at the center of the wafer vs. the edge. The method of this invention, the oxidized sidewall image transfer method, is much less dependent upon the local topographic nature, or wafer location.

These advantages translate into the capability of using oxide side strips 100 of a thickness of between about 1 nm and 50 nm, with a typical range of between about 5 nm and 25 nm.

FIG. 2 shows two oxidized sidewalls but it is possible to define the silicon comprising layer 110 to have one, or many, oxidized sidewalls which can be used for masking.

The oxidation sidewall image transfer technique can be widely used for patterning practically any article. In an exemplary embodiment the oxidation sidewall image transfer technique can be used to pattern gates for FET devices, typically for MOSFET devices.

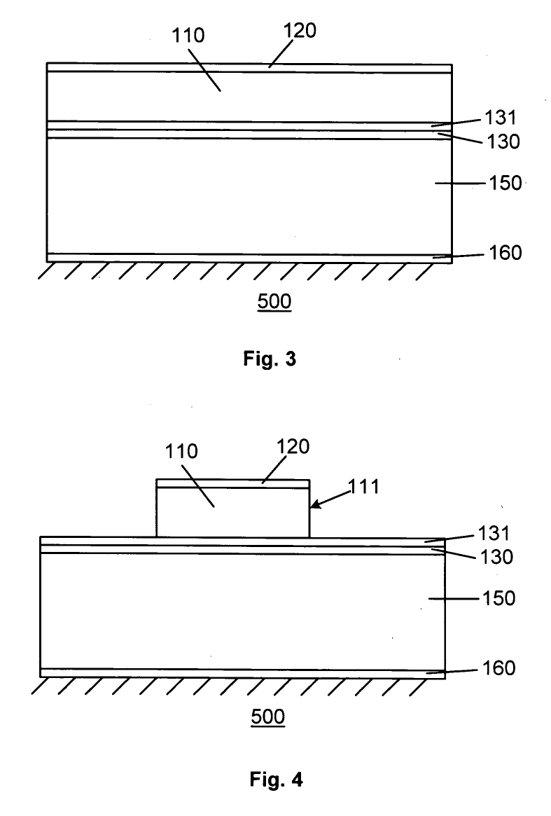

FIGS. 3 to 10 show schematic cross sectional views of an exemplary embodiment in the process steps for MOSFET gate fabrication using oxidation sidewall image transfer patterning.

The MOSFET fabrication can follow one of many variations know in the art before and after the disclosed gate patterning steps. FIG. 3 shows a preferred initial stage of the patterning technique. A gate dielectric layer 160 is in place over the device material 500. The preferences for device material 500 can vary broadly, as they are known in the arts. A layer of a first material 150 which is suitable for being the gate material of a MOSFET is in place over the gate dielectric 160. In an exemplary embodiment the first material 150 can be doped, or undoped, poly-Si in the thickness range of between about 50 nm to 150 nm, but in further embodiments other substances, or compounds, also suitable for gate material, could be used as well. Such suitable gate materials, for instance, can be short polysilicon gate lines for fully silicide gates, poly/dual metal stack gates, sacrificial gate structures for replacement gate lines for dual work function metal gate, or other advanced gate stack integration schemes known in the art. On top of the first material layer 150 in a representative embodiment a hard mask layer follows, which can typically comprise a nitride layer 130 and an oxide layer 131. In certain embodiments the hard mask layer may be omitted entirely. Next, a silicon comprising layer 110, typically an amorphous Si layer, with a thickness of between about 10 nm and 70 nm, follows. The amorphous Si layer 110 is covered with a cap-layer, typically a nitride layer 120 of between about 1 nm and 25 nm thickness. The placing, or depositing of these layers follows methods known in the art.

FIG. 4 schematically shows a next stage in the process. Using conventional techniques the nitride cap-layer 120 and amorphous Si layer 110 have been patterned and etched. In this manner at least one sidewall 111 on the amorphous Si layer 110 has been exposed.

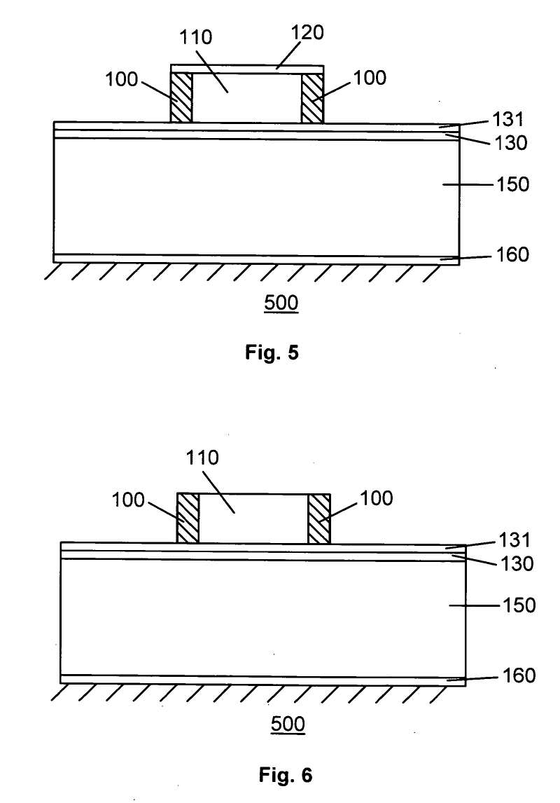

FIG. 5 shows the gate fabrication process at the stage where the sidewalls of the amorphous Si layer 110 have been oxidized, forming oxide strips 100. The cap-layer 120 prevented oxide formation on other than sidewall 111 surfaces. The oxidation of the sidewall 111 can be conventional thermal, plasma, ozone, rapid thermal, vapor addition, or any other known method in the art that forms well controlled uniform oxide thicknesses. The oxide strips 100 are between about 1 nm and 50 nm, typically between 5 nm and 25 nm thick.

In FIG. 6 the cap-layer 120, typically a nitride layer, has been removed by selective wet or dry etching as known in the art. A typical wet etching process for removal nitride is called Hot Phosphoric Acid Etch. A typical dry etch process of nitride removal with selectively to oxide and Si is the following: using a mix of fluorocarbon gases, such CF₄, CHF₃, CH₂F₂, CH₃F, with oxygen, CO or CO₂, or H₂, with other inert gases, such as Ar, or He, with process pressure ranging from 15 to 100 mTorr, rf power ranging from 50-400 Watts, and done in a typical capacitively coupled plasma etching chamber; or using SF₆, NF₃, HBr, Cl₂, O₂, He, Ar, etc gas mixture plasmas with pressure ranging from 3 to 50 mTorr, and rf source power from 50 to 400 Watts, with rf power on wafer chuck ranging from 10 to 150 Watts, and done in a typical inductively coupled plasma chamber.

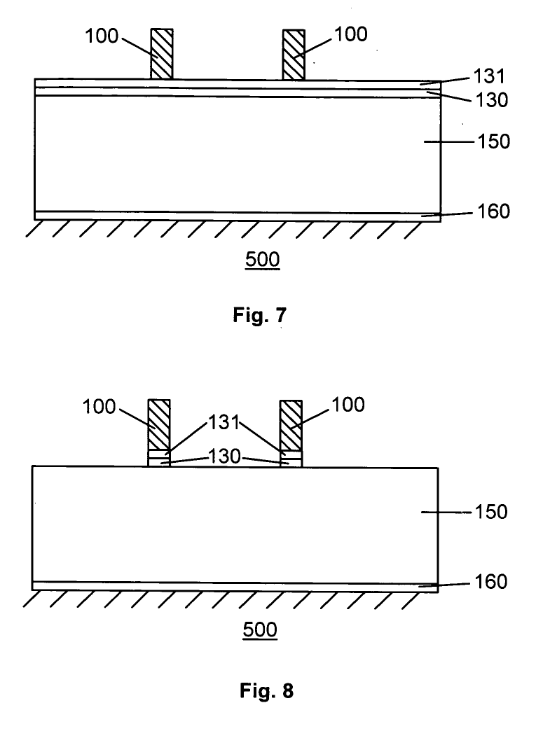

In FIG. 7 the amorphous Si layer 110 has been removed by selective wet or dry etching as known in the art, while leaving in place the oxide strips 100. The standing oxide strips 100 become masks for transferring their image, or footprint, to the layers lying below, to the first material 150, and the optional a hard mask layer of nitride 130 and oxide 131. Typical process-parameters are using bromine (Br) and chlorine (Cl) mixture with oxygen based plasma with some inert gases, such as, helium (He) or argon (Ar), process pressure ranging from 3 to 75 mTorr, and rf source power of 100 to 800 Watts, done in an inductive coupled plasma chamber.

FIG. 8 shows that using the oxide strips 100 as masks, the nitride 130 and oxide 131 hard mask layers have been opened by selective etching as known in the art. Typical process parameters are: using fluorocarbon gases, such as CF₄, CHF₃, CH₂F₂, CH₃F, C₂F₄, mixture with oxygen, hydrogen, CO, or CO₂, based plasma with some inert gases, such as, helium (He) or argon (Ar), with process pressure ranging from 15 to 200 mTorr, and rf source power of 100 to 400 Watts, done in a capacitively coupled plasma chamber; or using SF₆, NF₃, HBr, C1₂, O₂, He, Ar, etc gas mixture plasmas with pressure ranging from 3 to 50 mTorr, and rf source power from 50 to 400 Watts, and rf power on wafer chuck ranging from 10 to 150 Watts, done in an inductively coupled plasma chamber.

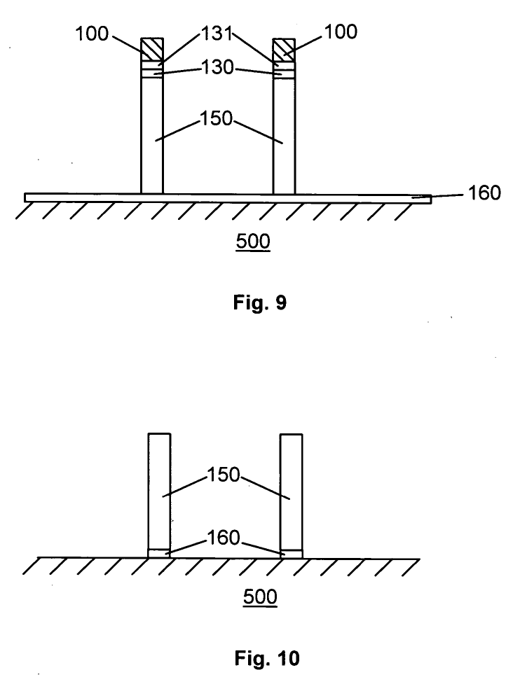

In FIG. 9, using the oxide strips 100 and the optional nitride 130 and oxide 131 hard mask layers, the first material 150, which is suitable for being the gate material of a MOSFET, has been patterned with a selective etch as known in the art. Typical process parameters are of multiple steps of process sequences are, for example: (1) Break through step to remove a thin layer of native oxide from the top of the first material 150, when the first material is silicon, using bromine (Br) and/or chlorine (Cl) mixture with oxygen based plasmas pressure ranging from 3 to 20 mTorr, 200 to 600 Watts rf source power and 200-600 Watts of wafer chuck rf power for 5-20 seconds; (2) main etching step, in which the main part of the first material 150 is etched, using bromine (Br) and/or chlorine (Cl) mixture with oxygen and/or some inert gases, such as, helium (He), based plasmas; with pressure ranging from 3 to 20 mTorr, and 100 to 500 Watts rf source power and 10-150 Watts of wafer chuck rf power for 10-100 seconds; (3) Soft-landing step, which has higher selectivity to the underneath gate dielectric layer 160, such as oxide or oxynitride, using bromine (Br) mixture with oxygen and/or some inert gases, such as, helium (He), based plasmas, with pressure ranging from 5 to 50 mTorr, and 100 to 500 Watts rf source power and 25-150 Watts of wafer chuck rf power, variety of endpoint techniques, such optical emission system (OES), being used to monitor and determine actual etch time of this step; (4) over etching step, with a typical selectivity being 250-500:1 to clean up the gate dielectric layer 160, such as oxide or oxynitride, removing any remaining or residual first material 150 which is not under the masks, using bromine (Br) mixture with oxygen and/or some inert gases, such as, helium (He), based plasmas, with pressure ranging from 20 to 100 mTorr, and 200 to 500 Watts rf source power and 25-150 Watts of wafer chuck rf power, typically etching time being 30-100 seconds. The thickness of the masking layers may change during all of the previous processing steps, as the selectivity of the etching techniques is usually less than 100%.

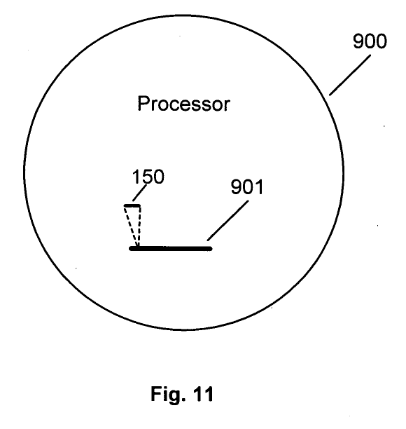

FIG. 10 shows the state when the masking layers 100, 131, and 130 have all been removed. Also, optionally, the gate dielectric layer 160 can be patterned in these steps, leaving in place the gate dielectric layer 160 only underneath the first material 150. Typical removal process is a wet etching step by dip into 10-200:1 diluted HF (DHF) for a period of 20-600 seconds.

All the described processing step are exemplary embodiments, and one skilled in the art would recognize that alternate processing steps may also be employed for the removal of various layers during patterning.

Beyond the state as schematically depicted on FIG. 10 the MOSFET fabrication is preferably progressing with steps known in the art.

FIG. 11 shows a symbolic view of an electronic processor 900 containing at least one chip 901 in the fabrication of which MOSFET devices had their gates patterned with the steps of oxidation sidewall patterning disclosed in this invention. The processor 900 can be any processor which can benefit from MOSFETs processed using the oxidation sidewall patterning method. Representative embodiments of processors such manufactured are digital processors, typically found in the central processing complex of computers; mixed digital/analog processors; and any processor in general which is need of high performance that the short gates of the oxidation sidewall patterning method enables.

Many modifications and variations of the present invention are possible in light of the above teachings, and could be apparent for those skilled in the art. The scope of the invention is defined by the appended claims.

We claim:

1. A method for patterning an article, comprising the steps of:
forming a silicon comprising layer over said article, wherein said silicon comprising layer is having at least one sidewall;
growing an oxide strip on said at least one sidewall;
removing said silicon comprising layer while leaving said oxide strip in place; and
using said oxide strip as mask in the patterning of said article.

2. The method of claim 1, wherein said oxide strip is grown to a thickness of between about 1 nm and 50 nm.

3. The method of claim 2, wherein said oxide strip is grown to a thickness of between about 5 nm and 25 nm.

4. The method of claim 1, wherein said silicon comprising layer is selected to be between about 10 nm and 70 nm thick.

5. The method of claim 4, further comprising the step of depositing a cap-layer of between about 1 nm and 25 nm thickness on top of said silicon comprising layer.

6. The method of claim 5, wherein said cap-layer is selected to be a nitride layer.

7. The method of claim 4, wherein said silicon comprising layer is selected to be amorphous Si.

8. The method of claim 1, wherein said article is selected to be a layered structure.

9. The method of claim 8, wherein said layered structure is selected to comprise a layer of a first material, wherein said first material is suitable for being the gate material of a FET.

10. The method of claim 9, wherein said layered structure is selected to further comprise a hard mask layer over said first material.

11. The method of claim 10, wherein said hard mask layer is selected to comprise a nitride layer over said first material and an oxide layer over said nitride layer.

12. The method of claim 11, wherein said layered structure is selected to further comprise a gate dielectric layer underneath said first material.

13. A method for patterning a MOSFET gate, comprising the steps of:
forming a layer of a first material over a gate dielectric of said MOSFET;
depositing an amorphous Si layer of between about 10 nm and 70 nm thickness over said first material;
depositing a nitride cap-layer on top of said amorphous Si layer;
patterning said nitride cap-layer and said amorphous Si layer, wherein sidewalls are exposed on said amorphous Si layer;
growing oxide strips on said sidewalls to a thickness of between about 1 nm and 50 nm;
removing said patterned nitride cap-layer and said amorphous Si layer while leaving said oxide strips in place; and
using said oxide strips as mask in the patterning of said first material.

14. The method of claim 13, wherein said oxide strips are grown to a thickness of between about 5 nm and 25 nm.

15. The method of claim 13, further comprising the step of placing a hard mask layer between said layer of said first material and said amorphous Si layer.

16. The method of claim 15, wherein said hard mask layer is selected to comprise a nitride layer over said first material and an oxide layer over said nitride layer.

17. A method for fabricating an electronic processor comprising MOSFET devices, comprising the step of:
patterning gates for said MOSFET devices, said patterning comprises the steps of:
forming a layer of a first material over gate dielectrics of said MOSFET devices;
depositing an amorphous Si layer of between about 10 nm and 70 nm thickness over said first material;
depositing a nitride cap-layer on top of said amorphous Si layer;
patterning said nitride cap-layer and said amorphous Si layer, wherein sidewalls are exposed on said amorphous Si layer;
growing oxide strips on said sidewalls to a thickness of between about 1 nm and 50 nm;
removing said patterned nitride cap-layer and said amorphous Si layer while leaving said oxide strips in place; and
using said oxide strips as mask in the patterning of said first material.

18. The method of claim 17, wherein said oxide strips are grown to a thickness of between about 5 nm and 25 nm.
